(19) United States
(12) Patent Application Publication
(10) Pub. No.: US 2009/0315034 A1
(43) Pub. Date: Dec. 24, 2009

(54) Thin Film Transistor (TFT), method of fabricating the TFT, and Organic Light Emitting Diode (OLED) display including the TFT

(76) Inventors: Jae-Seob Lee, Yongin-City (KR); Eun-Hyun Kim, Yongin-City (KR)

Correspondence Address: ROBERT E. BUSHNELL & LAW FIRM, 2029 K STREET NW, SUITE 600, WASHINGTON, DC, 20006-1004, US

(21) Appl. No.: 12/453,932

(22) Filed: May 27, 2009

(30) Foreign Application Priority Data
Jun. 19, 2008 (KR) 10-2008-0057922

(51) Int. Cl. H01L 29/786; H01L 21/336

(52) U.S. Cl. 257/66; 438/158; 257/E29.294; 257/E21.414

(57) ABSTRACT

A Thin Film Transistor (TFT) includes: a substrate, a buffer layer arranged on the substrate, a gate electrode arranged on the buffer layer, a gate insulating layer arranged on the gate electrode, a semiconductor layer arranged on the gate insulating layer to correspond to the gate electrode, a heat transfer sacrificial layer arranged on the semiconductor layer, and source and drain electrodes connected to the semiconductor layer. A method of fabricating the TFT and a method of fabricating an Organic Light Emitting Diode (OLED) display having the TFT is also provided.

### CLAIM OF PRIORITY

This application makes reference to, incorporates the same herein, and claims all benefits accruing under 35 U.S.C. §119 from an application earlier filed in the Korean Intellectual Property Office on Jun. 19, 2008 and there duly assigned Serial No. 10-2008-0057922.

### BACKGROUND OF THE INVENTION

1. Field of the Invention

The present invention relates to a Thin Film Transistor (TFT), a method of fabricating the TFT, and an Organic Light Emitting Diode (OLED) display, and more particularly, the present invention relates to a TFT fabricated by forming a metal cap on an amorphous silicon layer, irradiating the metal cap with a laser, and forming a polycrystalline silicon layer having uniform crystallinity using heat conduction during crystallization, and an OLED display including the TFT.

2. Description of the Related Art

Recently, flat panel display devices, such as Active Matrix Liquid Crystal Displays (AMLCDs), Field Emission Displays (FEDs), and Organic Light Emitting Diode (OLED) displays have attracted attention as high-end displays, which employ Thin Film Transistors (TFTs) to operate pixels.

TFTs are usually formed of silicon, which has higher field effect mobility in a polycrystalline state than in an amorphous state, and thus, the flat panel displays can be operated at a high speed.

In the flat panel display, a substrate may be formed of single crystalline silicon, quartz, glass or plastic, and preferably glass due to low cost, transparency and easiness in fabrication.

However, to crystallize amorphous silicon formed on a glass substrate into polycrystalline silicon, an annealing process has to be performed within a temperature range at which the glass substrate will not be deformed.

An example of a Low Temperature PolySilicon (LTPS) technique is a laser annealing technique. The laser annealing technique has been known to be better than other low temperature crystallization techniques due to low production cost and high efficiency.

Generally, for laser annealing, an excimer laser is widely used. The laser annealing technique using an excimer laser can heat and melt amorphous silicon in a short time to form polycrystalline silicon since a laser wavelength used therein has a high absorption rate with respect to the amorphous silicon, and thus, a substrate is not damaged by the laser.

However, it is difficult to apply the excimer laser annealing technique to fabrication of a poly-Silicon Thin Film Transistor (p-Si TFT) used in a high quality flat panel display due to low electron mobility of the polycrystalline silicon formed by the technique and non-uniformity in all TFTs.

Moreover, to form a large-sized substrate using the well known laser annealing technique, p-Si TFT is fabricated on the entire surface of the large-sized substrate by irradiating and scanning laser beams several times. When laser beams are scanned again at a region through which initial laser beams pass, crystallized silicon is melted and thus second crystallization is induced at the scanned region. As a result, the secondary-crystallized polycrystalline silicon formed at the region where laser beams partially overlap has different crystal characteristics from polycrystalline silicon which is not subjected to the secondary crystallization.

Accordingly, when the p-Si TFTs are fabricated using the well-known laser annealing technique, the p-Si TFTs having different crystal characteristics from each other are formed on one substrate, and thus a flat panel display using such p-Si TFTs has defects, such as mura formed along recrystallized polycrystalline silicon.

### SUMMARY OF THE INVENTION

Aspects of the present invention provide a TFT and an OLED display having the TFT, which is fabricated by forming a metal cap on an amorphous silicon layer, irradiating the metal cap with a laser, and crystallizing the amorphous silicon layer into a polycrystalline silicon layer having uniform crystallinity using heat conduction.

According to an embodiment of the present invention, a TFT includes: a substrate; a buffer layer arranged on the substrate; a gate electrode arranged on the buffer layer; a gate insulating layer arranged on the gate electrode; a semiconductor layer arranged on the gate insulating layer to correspond to the gate electrode; a heat transfer sacrificial layer disposed on the semiconductor layer; and source and drain electrodes connected to the semiconductor layer.

According to another embodiment of the present invention, a method of fabricating a TFT includes: preparing a substrate; forming a buffer layer on the substrate; forming a gate electrode on the buffer layer; forming a gate insulating layer on the substrate; forming an amorphous silicon layer on the gate insulating layer; forming a heat transfer sacrificial layer on the amorphous silicon layer; irradiating a laser beam to the heat transfer sacrificial layer to crystallize the amorphous silicon layer into a polycrystalline silicon layer; at least partially removing the heat transfer sacrificial layer; patterning the polycrystalline silicon layer and forming a semiconductor layer; and forming source and drain electrodes connected to the semiconductor layer corresponding to the gate electrode. A method of fabricating an organic light emitting diode display device having the TFT is also provided.

Additional aspects and/or advantages of the present invention are forth in part in the description which follows and, in part, will be apparent from the description, or may be learned by practice of the present invention.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIGS. 1A to 1D are cross-sectional views of a bottom-gate TFT according to an embodiment of the present invention;

FIGS. 2A to 2E are cross-sectional views of a top-gate TFT according to an embodiment of the present invention;

FIG. 3 is a cross-sectional view of an OLED display according to an embodiment of the present invention; and

FIG. 4 is a photograph of a semiconductor layer according to an embodiment of the present invention.

### DETAILED DESCRIPTION OF THE INVENTION

Reference is made in detail below to the present embodiments of the present invention, examples of which are shown in the accompanying drawings, wherein like reference numerals refer to the like elements throughout the specification. The embodiments are described below in order to explain the present invention by referring to the figures.

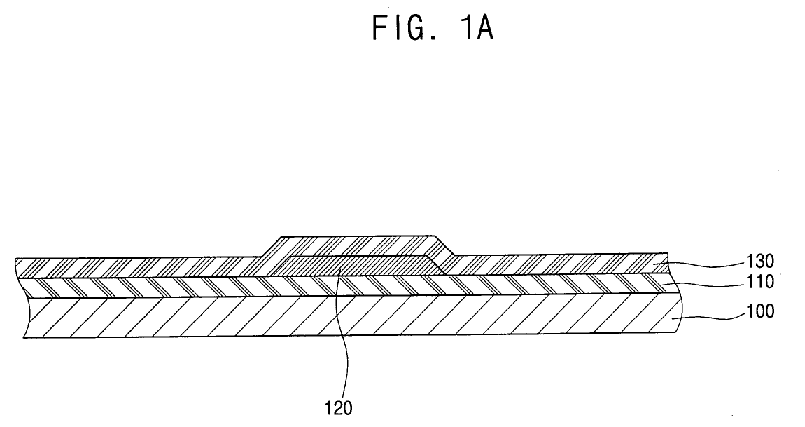

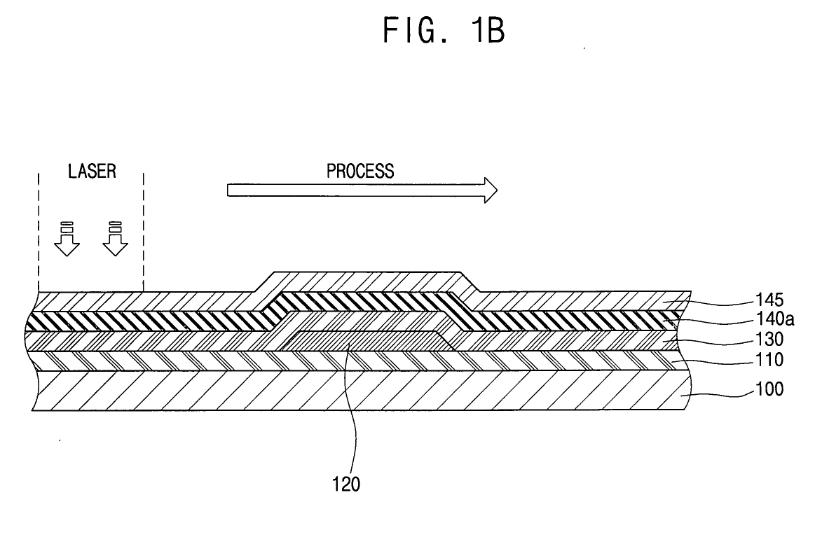

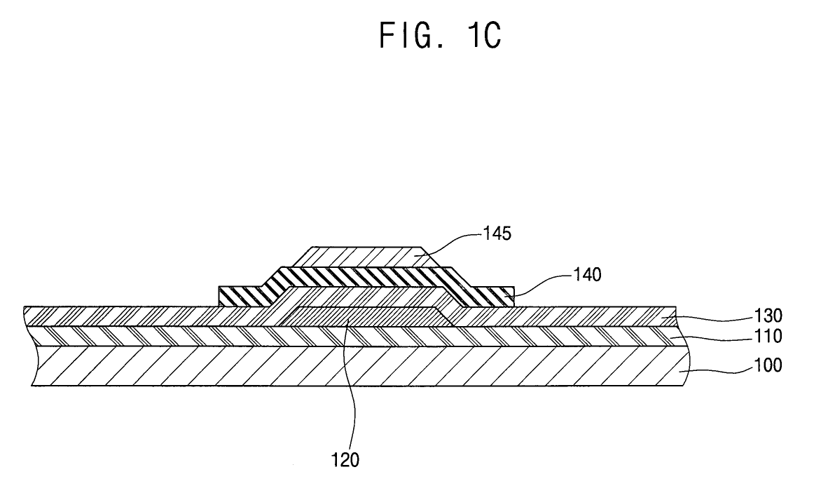

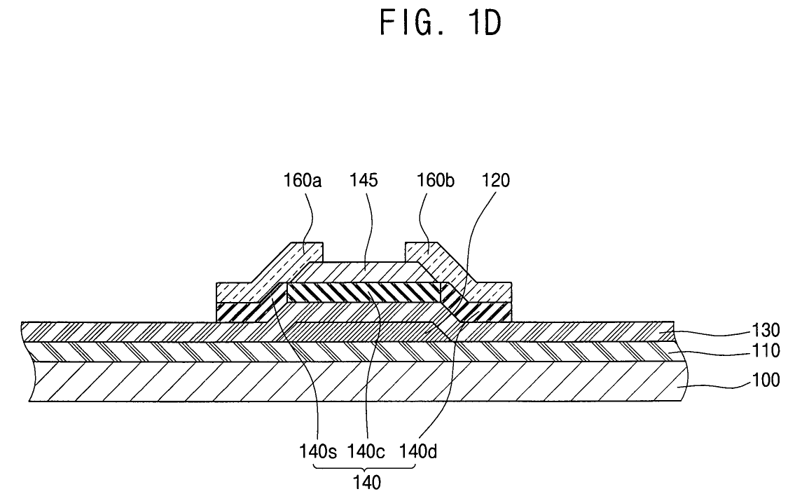

FIGS. 1A to 1E are cross-sectional views of a bottom-gate TFT according to an embodiment of the present invention.

Referring to FIG. 1A, a substrate 100 is formed, and a buffer layer 110 is formed on the substrate 100. The substrate 100 is a transparent insulating substrate formed of glass or plastic, and the buffer layer 110 may be formed of silicon oxide, silicon nitride or a combination thereof.

After that, a gate electrode 120 is formed on the buffer layer 110, and a gate insulating layer 130 is formed on the gate electrode 120.

Then, an amorphous silicon layer 140a is formed on the gate insulating layer 130, and a heat transfer sacrificial layer 145 is formed on the amorphous silicon layer 140a.

The heat transfer sacrificial layer 145 is arranged on the amorphous silicon layer 140a to prevent adsorption or diffusion of organic/inorganic impurities to a surface of the amorphous silicon layer 140a. Furthermore, the heat transfer sacrificial layer 145 transfers heat generated by a solid laser to the amorphous silicon layer 140a, thereby crystallizing the amorphous silicon layer 140a. The heat transfer sacrificial layer 145 is formed of molybdenum tungsten (MoW), silicon oxide or silicon nitride, and has a thickness of about 50 to 300 nm. When the thickness of the heat transfer sacrificial layer is less than 50 nm, it is so thin that too much heat may be transferred to the amorphous silicon layer by the irradiating laser, and thus, the amorphous silicon layer may be melted and then become solid, thereby causing defects in the crystalline silicon. On the other hand, when the thickness of the heat transfer sacrificial layer is more than 300 nm, heat cannot be sufficiently transferred to the amorphous silicon layer, so that it may not be properly crystallized. For these reasons, this thickness range is preferable to form a polycrystalline silicon layer having uniform crystallinity by solid-phase crystallization.

Referring to FIG. 1B, crystallization is performed by irradiating laser beams on the substrate 100 having the heat transfer sacrificial layer 145. The laser is a solid type, which may be a green laser having a wavelength of 532 nm, or a laser diode having a wavelength of 808 nm. The green laser irradiates with pulses with an intensity of 600 to 1000 mJ/cm² at a scan speed of 20 to 100 mm/s. The laser diode is a continuous wave, which irradiates with an intensity of 0.25 kw/cm² at a scan speed of 20 to 100 mm/s. Thus, the amorphous silicon layer may be crystallized into a polycrystalline silicon layer, which has uniform grains but no grain boundary.

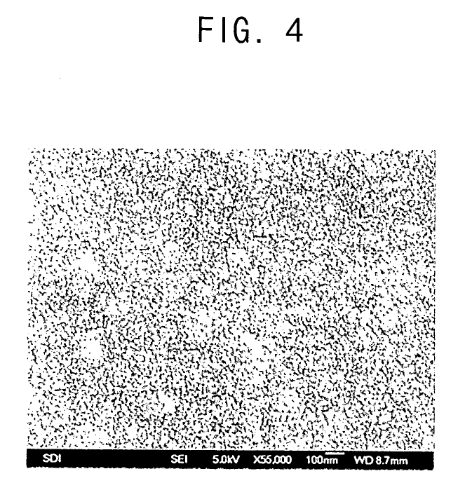

FIG. 4 is a photograph of the polycrystalline silicon layer crystallized as described above. Referring to FIG. 4, it can be noted that the polycrystalline silicon layer subjected to the crystallization under the above conditions has uniform grains having a size of 20 nm or less, but does not have a grain boundary.

Subsequently, referring to FIG. 1C, the amorphous silicon layer 140a is crystallized into the polycrystalline silicon layer (not illustrated) by solid phase crystallization without melting the amorphous silicon layer 140a, and the heat transfer sacrificial layer 145, except for a part corresponding to the gate electrode 120, is removed by etching, thereby patterning the polycrystalline silicon layer. Accordingly, a semiconductor layer 140 is formed. The heat transfer sacrificial layer 145 serves to protect the semiconductor layer 140 from being etched. The heat transfer sacrificial layer can remain, only when it is formed of silicon oxide or silicon nitride, and thus, when it is formed of MoW, it has to be completely etched.

Referring to FIG. 1D, source and drain electrodes 160a and 160b are arranged at edges of the heat transfer sacrificial layer 145 other than that corresponding to the gate electrode 120, and connected to the semiconductor layer 140 formed as described above. Thus, a TFT having the semiconductor layer 140, which includes source/drain regions 140s and 140d and a channel region 140c, is completed.

The gate electrode 120 may be formed of a material selected from the group consisting of aluminum (Al), an Al alloy, Mo and a Mo alloy, and is preferably formed of a MoW alloy.

The gate insulating layer 130 may be formed of silicon nitride, silicon oxide or a combination thereof.

Exemplary embodiment 2 is the same as Exemplary embodiment 1 except for the position of a gate electrode, and thus, repeated descriptions thereof have been omitted for convenience.

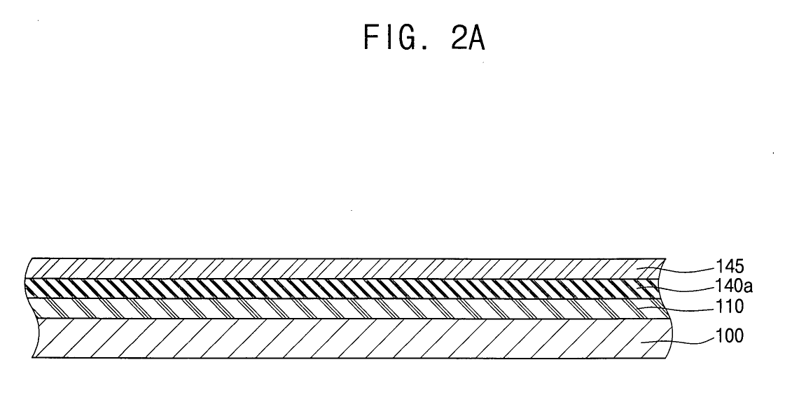

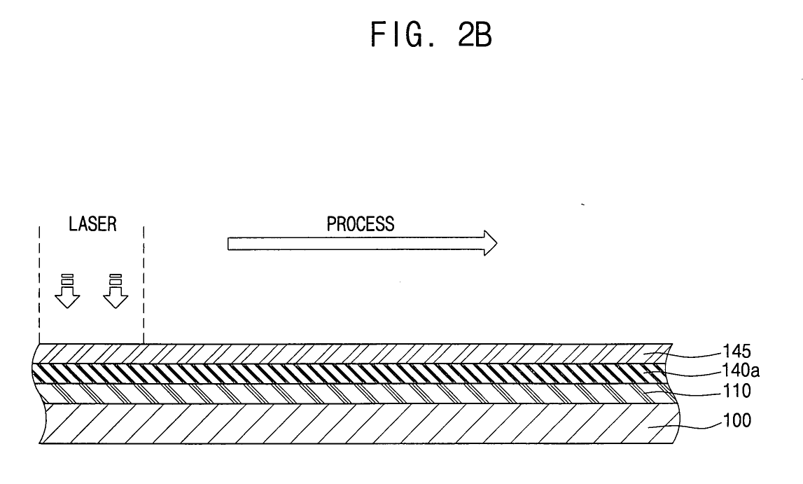

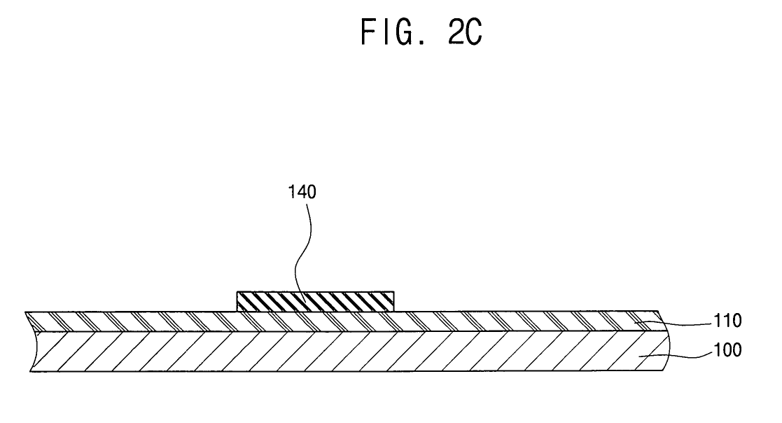

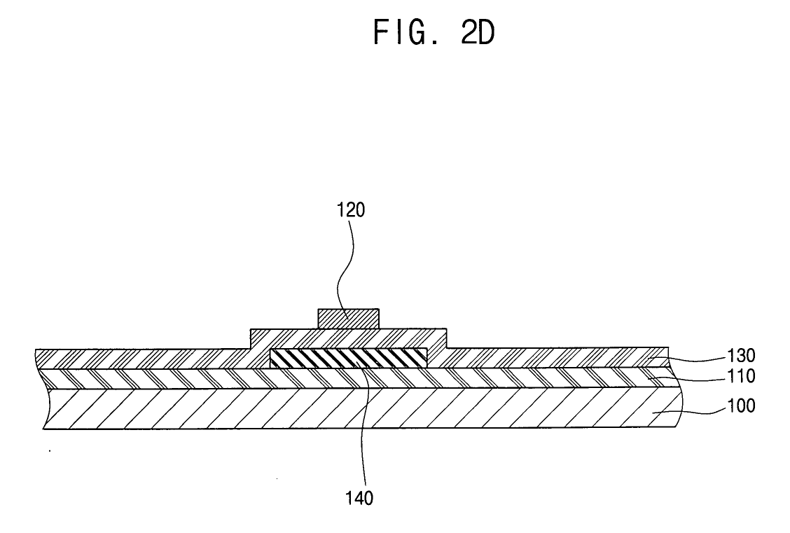

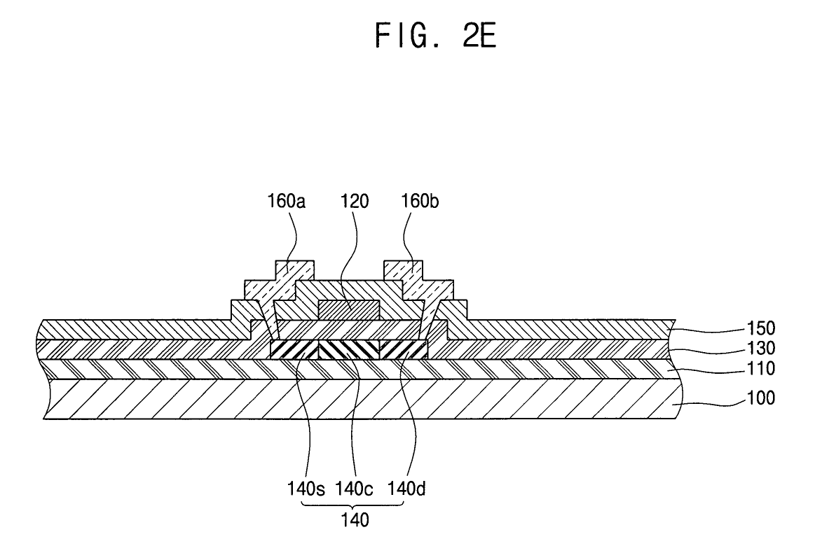

Referring to FIG. 2A, a substrate 100 is provided, and a buffer layer 110 is formed on the substrate 100. An amorphous silicon layer 140a is formed on the buffer layer 110, and a heat transfer sacrificial layer 145 is formed on the amorphous silicon layer 140a. The heat transfer sacrificial layer 145 is formed to a thickness of 50 to 300 nm as in Exemplary embodiment 1, and is formed of MoW, silicon oxide or silicon nitride.

After that, the amorphous silicon layer 140a is crystallized into a polycrystalline silicon layer (not illustrated) by laser irradiation under the same conditions as that of Exemplary embodiment 1. Then, the heat transfer sacrificial layer 145 is removed by etching.

Referring to FIG. 2C, a semiconductor layer 140 is formed by patterning the polycrystalline silicon layer (not illustrated), which is formed by crystallization of the amorphous silicon layer 140a.

Referring to FIG. 2D, a gate insulating layer 130 is formed on the semiconductor layer 140, and a gate electrode 120 is formed on the gate insulating layer 130 to correspond to the semiconductor layer 140.

Subsequently, referring to FIG. 2E, an interlayer insulating layer 150 is formed on the entire surface of the substrate having the gate electrode 120, and source and drain electrodes 160a and 160b are formed in contact with source and drain regions 120a and 120d, except for a part corresponding to a channel region 120c of the semiconductor layer 120. Thus, a bottom-gate TFT according to the present invention is completed.

Exemplary embodiment 3 has an OLED display having the bottom-gate TFT described in Exemplary embodiment 1, and thus descriptions overlapping with those of Exemplary embodiment 1 have been omitted.

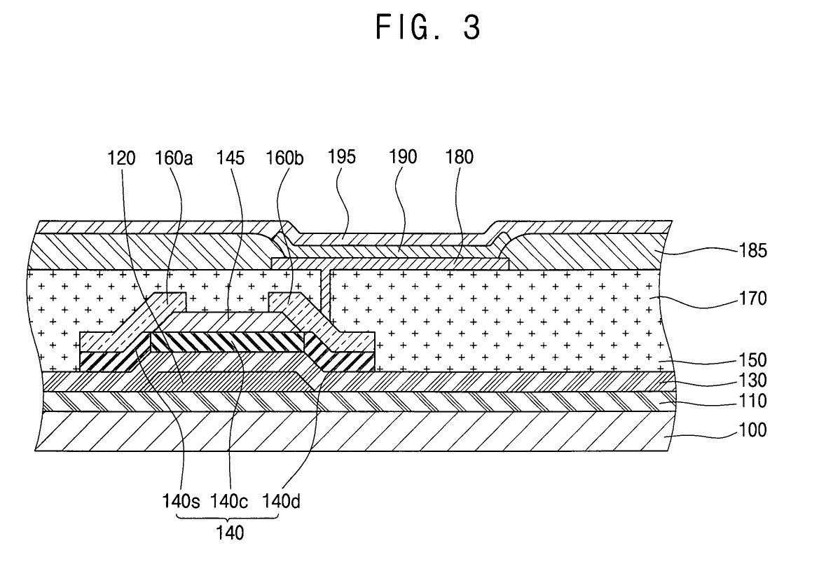

FIG. 3 is a cross-sectional view of an OLED display according to an embodiment of the present invention.

Referring to FIG. 3, a passivation layer 170 is formed on the source and drain electrodes 160a and 160b of the TFT described in Exemplary embodiment 1.

Subsequently, a pixel defining layer 185 defining a pixel is formed on a first electrode 180 connected to one of the source and drain electrodes 160a and 160b, an organic layer 190 including an organic emission layer is formed on the first electrode 180, and a second electrode 195 is formed on the entire surface of the substrate 100.

Accordingly, the OLED display according to an embodiment of the present invention is completed.

The present invention provides a crystallization method effectively performed at low temperature using heat conduction occurring in a heat transfer sacrificial layer. This method can increase uniformity of crystals in a semiconductor layer, and make performances of TFTs uniform. This method can also ensure high productivity and save production costs in the fabrication of the TFT by using a low-cost laser.

Although exemplary embodiments of the present invention have been shown and described, it would be appreciated by those skilled in the art that modifications may be made to these embodiments without departing from the principles and spirit of the present invention, the scope of which is defined by the following claims.

What is claimed is:

1. A Thin Film Transistor (TFT), comprising:
a substrate;
a buffer layer arranged on the substrate;
a gate electrode arranged on the buffer layer;
a gate insulating layer arranged on the gate electrode;
a semiconductor layer arranged on the gate insulating layer to correspond to the gate electrode;
a heat transfer sacrificial layer arranged on the semiconductor layer; and
source and drain electrodes connected to the semiconductor layer.

2. The TFT according to claim 1, wherein the semiconductor layer comprises polycrystalline silicon having a grain size of 20 nm or less.

3. The TFT according to claim 1, wherein the semiconductor layer is free of grain boundaries.

4. The TFT according to claim 1, wherein the heat transfer sacrificial layer comprises either silicon oxide or silicon nitride.

5. The TFT according to claim 1, wherein the heat transfer sacrificial layer has a thickness in a range of 50 to 300 nm.

6. A method of fabricating a Thin Film Transistor (TFT), comprising:
preparing a substrate;
forming a buffer layer on the substrate;
forming an amorphous silicon layer on the buffer layer;
forming a heat transfer sacrificial layer on the amorphous silicon layer;
irradiating a laser beam on the heat transfer sacrificial layer to crystallize the amorphous silicon layer into a polycrystalline silicon layer;
removing the heat transfer sacrificial layer;
patterning the polycrystalline silicon layer and forming a semiconductor layer;
forming a gate insulating layer on the entire surface of the substrate having the semiconductor layer;
forming a gate electrode on the gate insulating layer; and
forming source and drain electrodes, the source and drain electrodes being insulated from the gate electrode and connected to the semiconductor layer.

7. The method according to claim 6, wherein the heat transfer sacrificial layer is formed to a thickness in a range of 50 to 300 nm.

8. The method according to claim 6, wherein the heat transfer sacrificial layer is formed of one of molybdenum tungsten, silicon nitride and silicon oxide.

9. The method according to claim 6, wherein the laser beam includes either a laser diode or a green laser.

10. The method according to claim 9, wherein the green laser having an intensity in a range of 600 to 1000 mJ/cm², or the laser diode having an intensity of 0.25 kw/cm² is irradiated in a range of 20 to 100 mm/s.

11. A method of fabricating a Thin Film Transistor (TFT), comprising:
preparing a substrate;
forming a buffer layer on the substrate;
forming a gate electrode on the buffer layer;
forming a gate insulating layer on the substrate;
forming an amorphous silicon layer on the gate insulating layer;
forming a heat transfer sacrificial layer on the amorphous silicon layer;
irradiating a laser beam on the heat transfer sacrificial layer to crystallize the amorphous silicon layer into a polycrystalline silicon layer;
at least partially removing the heat transfer sacrificial layer;
patterning the polycrystalline silicon layer and forming a semiconductor layer; and
forming source and drain electrodes, the source and drain electrodes being connected to the semiconductor layer corresponding to the gate electrode.

12. The method according to claim 11, wherein the heat transfer sacrificial layer is formed to a thickness in a range of 50 to 300 nm.

13. The method according to claim 11, wherein the heat transfer sacrificial layer is formed of one of molybdenum tungsten, silicon nitride and silicon oxide.

14. A method of fabricating an Organic Light Emitting Diode (OLED) display, comprising:
preparing a substrate;
forming a buffer layer on the substrate;
forming a gate electrode on the buffer layer;
forming a gate insulating layer on the substrate;
forming an amorphous silicon layer on the gate insulating layer;
forming a heat transfer sacrificial layer on the amorphous silicon layer;
irradiating a laser beam on the heat transfer sacrificial layer to crystallize the amorphous silicon layer into a polycrystalline silicon layer;
at least partially removing the heat transfer sacrificial layer;
patterning the polycrystalline silicon layer and forming a semiconductor layer;
forming source and drain electrodes, the source and drain electrodes being connected to the semiconductor layer corresponding to the gate electrode;
forming a passivation layer on the entire surface of the substrate;
forming a first electrode, connected to one of the source and drain electrodes, on the passivation layer;
forming a pixel defining layer on the first electrode;
forming an organic layer on the first electrode; and
forming a second electrode on the entire surface of the substrate.

15. The method according to claim 14, wherein the heat transfer sacrificial layer is formed of one of molybdenum tungsten, silicon nitride and silicon oxide.

16. The method according to claim 14, wherein the heat transfer sacrificial layer is formed to a thickness in a range of 50 to 300 nm.

17. The method according to claim 14, wherein the laser beam includes either a laser diode or a green laser.

18. The method according to claim 14, wherein the green laser having an intensity in a range of 600 to 1000 mJ/cm², or the laser diode having an intensity of 0.25 kw/cm² is irradiated in a range of 20 to 100 mm/s.
